(19) United States
(12) Patent Application Publication
(10) Pub. No.: US 2025/0149107 A1
(43) Pub. Date: May 8, 2025

(54) TEST DEVICE, OPERATING METHOD OF TEST DEVICE, AND SEMICONDUCTOR DEVICE TEST SYSTEM

(71) Applicant: Samsung Electronics Co., Ltd., Suwon-si (KR)

(72) Inventors: Sehoon Park, Suwon-si (KR); Hyounsoon Km, Suwon-si (KR); Donggun Kim, Suwon-si (KR); Joonyeon Kim, Suwon-si (KR); Hyungsoon Kim, Suwon-si (KR)

(21) Appl. No.: 18/669,872

(22) Filed: May 21, 2024

(30) Foreign Application Priority Data
Nov. 7, 2023 (KR) 10-2023-0153103

(51) Int. Cl. G11C 29/56; G01R 31/317; G01R 31/319

(52) U.S. Cl. CPC G11C 29/56008; G01R 31/31703; G01R 31/31905; G11C 2029/5602

(57) ABSTRACT

A test device includes a plurality of input/output terminals configured to be electrically connected to the devices formed on the wafer, a comparative circuit configured to receive a plurality of test signals from a device under test formed on the wafer, and generate a plurality of test result signals, based on the plurality of test signals, and a memory configured to receive the plurality of test result signals and store bad cell information and repair information related to the device under test, which are indicated by the plurality of test result signals, wherein the total number of the plurality of test signals received from the device under test at one time is an integer.

### CROSS-REFERENCE TO RELATED APPLICATION

This application is based on and claims priority under 35 U.S.C. § 119 to Korean Patent Application No. 10-2023-0153103, filed on Nov. 7, 2023, in the Korean Intellectual Property Office, the disclosure of which is incorporated by reference herein in its entirety.

### BACKGROUND

The inventive concept relates to a semiconductor device test device, an operating method of a test device, and a semiconductor device test system, and more particularly, to a semiconductor device test device including integer numbers of input and output resources.

Automatic test equipment (ATE) may be used to test a plurality of semiconductor devices formed on a wafer. Through input/output resources of the ATE, a test pattern may be provided to a device under test (DUT), and/or a test signal may be received from the DUT and the received signal may be analyzed, thereby testing whether there is a defect in the semiconductor devices.

The numbers of input/output resources of the ATE may be physically restricted. Accordingly, a burst length of the test signal received from the DUT may be increased according to the number of semiconductor devices formed on the wafer. When the burst length is increased, a test time required to test whether there is a defect in the semiconductor devices formed on the wafer is increased, and thus, costs of manufacturing the semiconductor devices may be increased.

### SUMMARY

The inventive concept provides a test device including integer numbers of input and output resources, which receive an integer number of test signals from devices under test included in a wafer, thereby reducing a test time required to test the devices under test.

Additional aspects will be set forth in part in the description which follows and, in part, will be apparent from the description, or may be learned by practice of the presented embodiments.

According to an aspect of the inventive concept, there is provided a test device including an input and output unit including a plurality of input/output terminals configured to be electrically connected to the devices formed on the wafer; a comparative circuit configured to receive a plurality of test signals from a device under test formed on the wafer, and generate a plurality of test result signals, based on the plurality of test signals; and a memory configured to receive the plurality of test result signals and store bad cell information and repair information related to the device under test, which are indicated by the plurality of test result signals, wherein the total number of the plurality of test signals received from the device under test at one time is an integer.

According to another aspect of the inventive concept, there is provided an operating method of a test device, including receiving a plurality of test signals from a device under test formed on the wafer; generating a plurality of test result signals, based on results of comparing the received plurality of test signals with a test reference voltage; storing bad cell information related to the device under test in a memory of the test device, based on the plurality of test result signals; and generating repair information corresponding to the bad cell information, wherein the total number of the plurality of test signals received from the device under test at one time is an integer.

According to another aspect of the inventive concept, there is provided a test system including a probe card including a plurality of input/output pins configured to be electrically connected to the devices formed on the wafer; and a test device configured to test a device under test formed on the wafer, wherein the probe card is configured to receive a plurality of test signals through the plurality of input/output pins from the device under test, and provide the received plurality of test signals to the test device, wherein the test device comprises: a plurality of input/output terminals configured to receive the plurality of test signals from the probe card; a comparative circuit configured to generate a plurality of test result signals, based on the plurality of test signals; and a memory configured to receive the plurality of test result signals and store bad cell information and repair information related to the device under test, which are indicated by the plurality of test result signals, wherein the total number of input and output pins from among the plurality of input/output pins electrically connected to the device under test is an integer.

### BRIEF DESCRIPTION OF THE DRAWINGS

Embodiments will be more clearly understood from the following detailed description taken in conjunction with the accompanying drawings in which:

FIG. 1 is a diagram showing a semiconductor device test system according to an embodiment;

FIGS. 2A and 2B are diagrams for describing a semiconductor device test system according to an embodiment;

FIGS. 3 and 4 are diagrams for describing a semiconductor device test system according to an embodiment;

FIGS. 5 and 6 are diagrams for describing a semiconductor device test system according to an embodiment;

FIGS. 7A and 7B are tables for describing a burst length of a test signal when a test is performed on devices under test, according to a semiconductor device test system, according to an embodiment; and

FIG. 8 is a flowchart for describing an operation method of a test device, according to an embodiment.

### DETAILED DESCRIPTION OF THE EMBODIMENTS

Hereinafter, some embodiments will be described in detail with reference to accompanying drawings. When describing the inventive concept with reference to the drawings, same reference numerals are assigned to same or corresponding components, and redundant descriptions thereof are omitted.

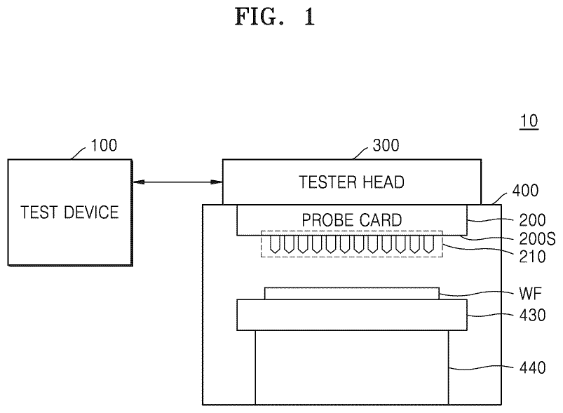

FIG. 1 is a diagram showing a semiconductor device test system 10 according to an embodiment.

Referring to FIG. 1, the semiconductor device test system 10 according to an embodiment may be a system for testing semiconductor devices formed on a wafer WF. In the present specification, the semiconductor device test system 10 may be simply referred to as a test system. The wafer WF may include a plurality of semiconductor devices. In the present specification, the plurality of semiconductor devices may be tested by a test device 100, and in this case, a semiconductor device to be tested may be referred to as a device under test.

According to an embodiment each of the semiconductor devices formed on the wafer WF may be any one of devices, such as dynamic random access memory (DRAM), static random access memory (SRAM), electrically erasable programmable read-only memory (EEPROM), phase-change random access memory (PRAM), and magnetoresistive random access memory (MRAM). However, this is only an example and the inventive concept is not limited thereto. Each of the semiconductor devices formed on the wafer WF may be any one of devices, such as complementary metal-oxide semiconductor (CMOS) image sensor (CIS), system large-scale integration (LSI), and flash memory.

The semiconductor device test system 10 may include the test device 100, a probe card 200, a tester head 300, and a test chamber 400.

The wafer WF may be loaded onto the test chamber 400 and then tested by the semiconductor device test system 10. The wafer WF may be formed of or include silicon (Si). The wafer WF may include a semiconductor element such as germanium (GE), or a compound semiconductor such as silicon carbide (SiC), gallium arsenide (GaAs), indium arsenide (InAs), or indium phosphide (InP).

According to an embodiment, the wafer WF may be loaded onto a chuck 430 such that access terminals of the device under test face the probe card 200. According to an embodiment, an electric die sorting (EDS) test may be performed in the test chamber 400. The EDS test refers to a process of applying an electrical signal to the device under test and determining a defect in semiconductor devices according to a signal output by the device under test, the output signal being based on the electrical signal.

According to an embodiment, the EDS test may include a direct current (DC) test and an alternating current (AC) test. Here, the DC test is a test of determining a defect in the device under test by applying specific electric potential to an input terminal of the device under test and measuring a DC characteristic of open/short, input current, output electric potential, and power current. Also, the AC test is a test of determining a defect in the device under test by applying a pulse signal to the input terminal of the device under test and measuring an operating characteristic of an input/output transport latency time and start/end time of an output signal.

The chuck 430 and a chuck driving device 440 may be arranged inside the test chamber 400. A plurality of pins 210 may be mounted on the probe card 200. An access region of the probe card 200 and the access terminals of the device under test may be electrically connected to each other through the plurality of pins 210. The plurality of pins 210 may include the plurality of pins 210 for connecting access terminals on the access region of the probe card 200 and the access terminals of the device under test to each other. The plurality of pins 210 may be, for example, a pogo pin, but are not limited thereto.

The chuck 430 may be disposed on the chuck driving device 440. The chuck 430 may fix the wafer WF via a method such as electrostatic adsorption or vacuum adsorption. The chuck driving device 440 may be disposed below the chuck 430 and connected to the chuck 430. The chuck driving device 440 may translate the chuck 430 in an X direction, a Y direction, and a Z direction. Also, the chuck driving device 440 may rotate the chuck 430. Here, the X direction and the Y direction may be two directions parallel to a first surface 200S of the probe card 200 and a surface facing the wafer WF inside the test chamber 400, and substantially perpendicular to each other (e.g., horizontal directions). The Z direction refers to a direction substantially perpendicular to the first surface 200S of the probe card 200 (e.g., a vertical direction). Unless specifically stated, definitions of directions are the same for all drawings below. For example, when only a portion (e.g., the probe card 200) of the semiconductor device test system 10 is illustrated, the definitions of the X direction, the Y direction, and the Z direction, based on the first surface 200S of the probe card 200, are the same as described above.

According to an embodiment, the chuck driving device 440 may rotate the chuck 430 based on an axis parallel to the Z direction such that the access terminals of the device under test formed on the wafer WF are aligned with respect to the access regions of the probe card 200. According to an embodiment, the chuck driving device 440 may move the chuck 430 in the X direction and the Y direction such that the access terminals of the device under test formed on the wafer WF are aligned perpendicularly to the access regions of the probe card 200. According to an embodiment, the chuck driving device 440 may move the chuck 430 in the Z direction such that the access terminals of the device under test formed on the wafer WF are electrically or physically connected to the access regions of the probe card 200.

According to an embodiment, the probe card 200 may be connected to the test device 100 through the tester head 300. Accordingly, an electrical signal generated in the test device 100 may be transmitted to the probe card 200. However, the inventive concept is not limited thereto, and the test device 100 may directly transmit a signal to the probe card 200.

According to an embodiment, the test device 100 may output the electrical signal required for an electrical characteristic test of the device under test formed on the wafer WF. According to an embodiment, the electrical signal output by the test device 100 may be applied to the device under test formed on the wafer WF, through the tester head 300 and the probe card 200. The device under test may perform an operation according to the applied electrical signal and generate a plurality of test signals. The plurality of test signals generated by the device under test may be transmitted to the test device 100 through the probe card 200 and the tester head 300. Here, the number of the plurality of test signals generated by the device under test may be an integer. For example, the number of the plurality of test signals generated by the device under test may be an integer of non-power-of-two (e.g., an integer that is not a power of two).

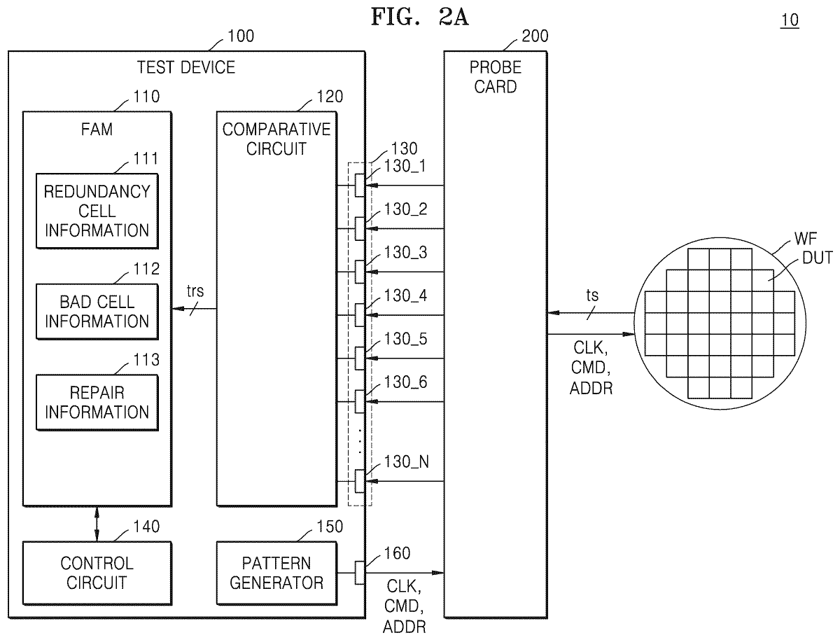

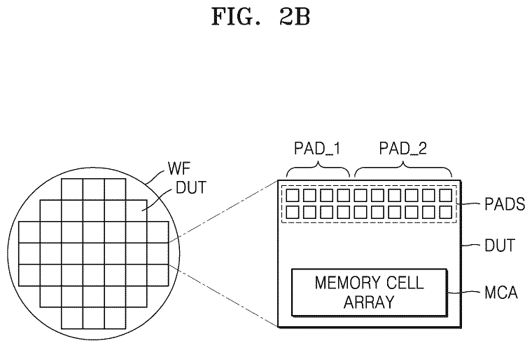

The test device 100 may include input and output resources (e.g., input/output resources), and may provide a test pattern to the device under test and/or receive a test signal from the device under test through the input and output resources. In the present specification, the test device 100 may denote automated test equipment (ATE). The input and output resources may denote, for example, input and output terminals (e.g., input/output terminals) of the test device 100. A detailed configuration of the test device 100 will be described below with reference to FIGS. 2A, 3, and 6.

According to an embodiment, the number of input and output resources of the test device 100 may be an integer (i.e., the number of input and output terminals included in the input and output resources). For example, the number of input and output resources of the test device 100 may be an integer of non-power-of-two.

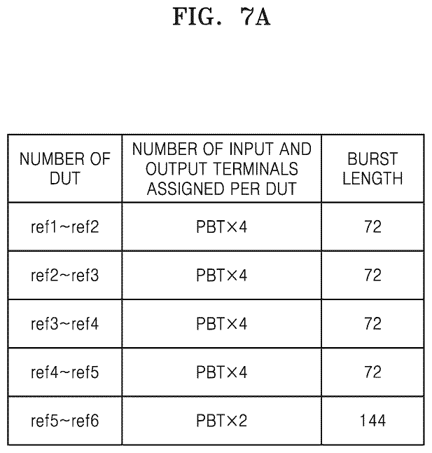

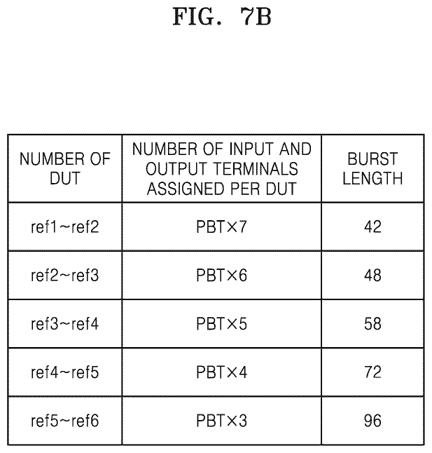

According to an embodiment, the number of input and output terminals of the test device 100, assigned to each device under test, may vary based on the number of the plurality of semiconductor devices formed on the wafer WF. The semiconductor device test system 10 may assign the input and output resources of the test device 100 to each device under test in integer units, based on the number of semiconductor devices formed on the wafer WF, and by assigning the input and output resources in integer units, a burst length of test signals received from the device under test may be decreased. A decrease in the burst length according to the number of the plurality of semiconductor devices formed on the wafer WF will be described below with reference to FIGS. 7A and 7B.

FIGS. 2A and 2B are diagrams for describing the semiconductor device test system 10 according to an embodiment. In particular, FIG. 2A is a diagram for describing a detailed configuration of the test device 100. FIG. 2B is a diagram for describing the wafer WF and a device under test DUT. FIGS. 2A and 2B may be described with reference to FIG. 1, and redundant descriptions may be omitted.

Referring to FIGS. 2A and 2B, the semiconductor device test system 10 may include the test device 100, the probe card 200, and the wafer WF.

The test device 100 may include a fail analysis memory (FAM) 110, a comparative circuit 120, input and output resources 130, a control circuit 140, a pattern generator 150, and a driver 160.

The test device 100 may be electrically connected to the wafer WF through the probe card 200. The wafer WF may include the plurality of semiconductor devices, and the test device 100 may perform an electrical test operation (e.g., an EDS test) on each of all semiconductor devices on the wafer WF. The plurality of semiconductor devices included in the wafer WF may be tested by the test device 100, and thus may be referred to as a device under test DUT.

The test device 100 may perform an electrical test on the device under test DUT included in the wafer WF to detect bad cells present in the device under test DUT. The test device 100 may replace the detected bad cells with redundancy cells such that the device under test DUT may function normally.

FIG. 2B is a diagram for describing the device under test DUT. Referring to FIG. 2B, each device under test DUT may include a memory cell array MCA including a plurality of memory cells configured to store data, and external connection pads PADS used to connect to an external device (e.g., the test device 100). The external connection pads PADS may be divided into first pads PAD_1 and second pads PAD_2.

According to an embodiment, the first pads PAD_1 may be configured to exchange a data signal between the test device 100 and the device under test DUT. According to an embodiment, the first pads PAD_1 may be referred to as data input and output pads (e.g., input/output pads). According to an embodiment, the data signal between the test device 100 and the device under test DUT may be referred to as a DQ signal. An example of the data signal exchanged between the test device 100 and the device under test DUT may include a test signal provided from the device under test DUT to the test device 100.

According to an embodiment, the second pads PAD_2 may be configured to exchange a clock signal CLK, a command signal CMD, and an address signal ADDR between the test device 100 and the device under test DUT.

According to an embodiment, the electrical test performed on the plurality of semiconductor devices included in the wafer WF may be simultaneously performed by the test device 100 in parallel. For example, the electrical test operation by the test device 100 may be performed simultaneously on all semiconductor devices present on the wafer WF, and such a test method may be referred to as a 1-shot test.

Referring back to FIG. 2A, the FAM 110 may be any hardware that may store information and is capable of being accessed by the control circuit 140. The FAM 110 may include, for example, read-only memory (ROM), random access memory (RAM), dynamic random access memory (DRAM), double-data-rate dynamic random access memory (DDR-DRAM), synchronous dynamic random access memory (SDRAM), static random access memory (SRAM), magnetoresistive random access memory (MRAM), programmable read only memory (PROM), erasable programmable read only memory (EPROM), electrically erasable programmable read only memory (EEPROM), flash memory, polymer memory, phase change memory, ferroelectric memory, silicon-oxide-nitride-oxide-silicon (SONOS) memory, magnetic card/disk, optical card/disk, or a combination of two or more thereof.

The information stored in the FAM 110 may include redundancy cell information 111, bad cell information 112, and repair information 113.

The redundancy cell information 111 may include information related to addresses of redundancy cells present in the device under test DUT. A redundancy cell may denote a cell designed as a spare to replace a bad cell in preparation for a case where there is a bad cell in a semiconductor device. According to an embodiment, the FAM 110 may further include a buffer memory, and the redundancy cell information 111 may be stored in the buffer memory. The bad cell information 112 may include information related to addresses of bad cells present in the device under test DUT. The repair information 113 may include information for repairing bad cells present in the device under test DUT. The information for repairing bad cells may be information in which an address of a bad cell and an address of a redundancy cell are mapped to each other. For example, when a first memory cell of a first device under test is a bad cell, the repair information 113 may include information in which an address of the first memory cell and an address of a redundancy cell corresponding to the first memory cell are mapped to each other.

According to an embodiment, the test device 100 may output, to the outside, the repair information 113 generated by performing an electrical test on the wafer WF.

The comparative circuit 120 may generate a plurality of test result signals trs, based on results of comparing a plurality of test signals ts received from the device under test DUT with a test reference voltage. The number of the plurality of test signals ts received by the comparative circuit 120 may be an integer. For example, the number of the plurality of test signals ts received by the comparative circuit 120 may be an integer of non-power-of-two.

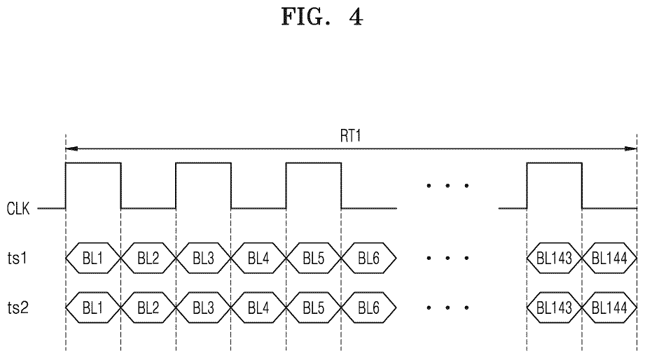

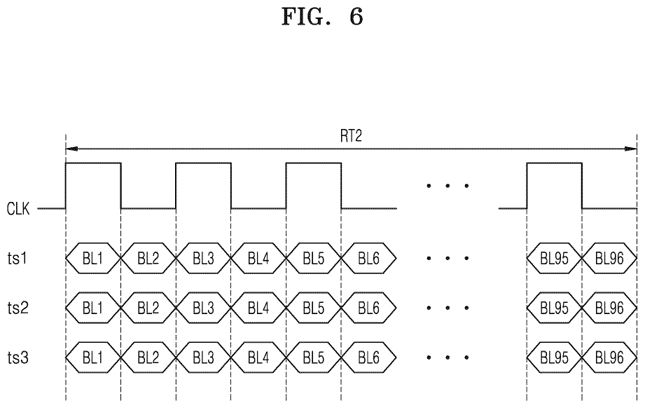

According to an embodiment, the test device 100 receiving the plurality of test signals ts by way of the comparative circuit 120 may be the test device 100 reading data stored in memory cells of the device under test DUT. Here, a time taken by the test device 100 to read each test signal may be referred to as a burst length. A burst length of one test signal may be divided into a plurality of burst durations. Here, each burst duration may correspond to a duration of reading two or more memory cells from among memory cells included in a memory cell array of a device under test. According to an embodiment, two or more memory cells corresponding to each burst duration may be adjacent memory cells from among memory cells present in a memory cell array of a device under test, and such adjacent two or more memory cells may be referred to as compressed memory cells. Examples related to a burst length and a burst duration will be described below with reference to FIGS. 4 and 6.

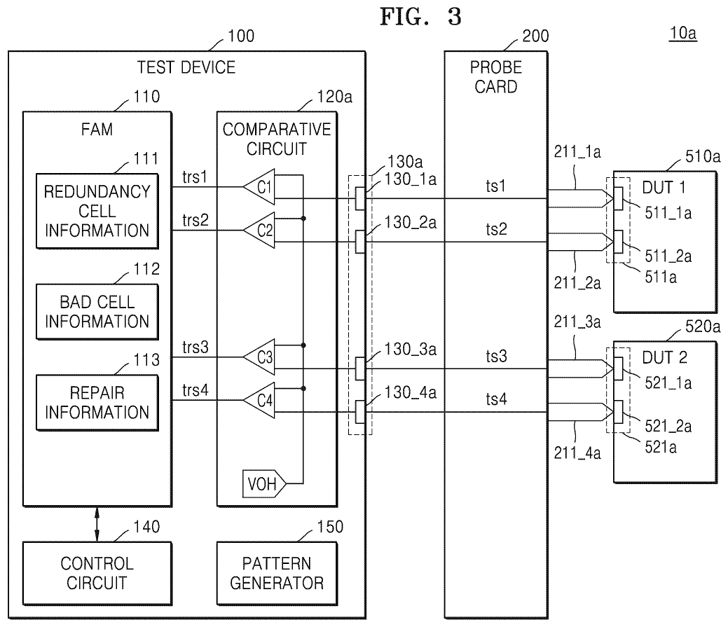

According to an embodiment, the comparative circuit 120 may include a plurality of comparators. The number of comparators included in the comparative circuit 120 may be an integer. For example, the number of comparators included in the comparative circuit 120 may be an integer of non-power-of-two. Detailed descriptions about the comparator will be described below with reference to FIGS. 3 and 6.

The comparative circuit 120 may provide the plurality of test result signals trs to the FAM 110. The number of the plurality of test result signals trs provided to the FAM 110 may be an integer. For example, the number of the plurality of test result signals trs provided to the FAM 110 may be an integer of non-power-of-two. The plurality of test result signals trs may include information about whether the device under test DUT has passed a test or not.

The test device 100 may provide a test pattern to the device under test DUT through the input and output resources 130 or receive a test signal from the device under test DUT through the input and output resources 130.

The input and output resources 130 may include a plurality of input and output terminals. For example, the input and output resources 130 may include first to Nth input and output terminals 130_1 to 130_N. Here, the number of input and output terminals included in the input and output resources 130 may be an integer, for example, may be an integer of non-power-of-two.

The control circuit 140 may generate the repair information 113, based on the bad cell information 112 and the redundancy cell information 111 stored in the FAM 110. The control circuit 140 may control the pattern generator 150 to provide the clock signal CLK, the command signal CMD, and the address signal ADDR to the device under test DUT. Here, signals generated by the pattern generator 150 may be provided to the device under test DUT through the driver 160. According to an embodiment, the control circuit 140 may generate the test reference voltage and provide the test reference voltage to the comparative circuit 120. However, this is only an example, and the test reference voltage may be generated through a separate voltage generation circuit included in the test device 100.

The probe card 200 may electrically connect the device under test DUT and the test device 100 to each other. The plurality of test signals ts generated by the device under test DUT may be provided to the test device 100 through the probe card 200. The probe card 200 may include a plurality of pins. The plurality of pins may include a plurality of input and output pins (e.g., input/output pins) electrically connected to the first pads PAD_1 of the device under test DUT, and here, the number of the plurality of input and output pins may be an integer. For example, the number of the plurality of input and output pins of the probe card 200 may be an integer of non-power-of-two. In the present specification, among the plurality of pins included in the probe card 200, pins electrically connected to the first pads PAD_1 that are data input and output pads of the device under test DUT may be referred to as input and output pins. The semiconductor device test system 10 according to an embodiment may be configured such that the test device 100 may receive the plurality of test signals ts from the device under test DUT through the probe card 200. Here, the number of the plurality of test signals ts may be an integer. For example, the number of the plurality of test signals ts may be an integer of non-power-of-two. As such, the test device 100 receives the number of test signals ts, the number being an integer of non-power-of-two, from the device under test DUT, and thus, burst lengths of the test signals ts may be reduced compared to when a power-of-two number of test signals ts is received. When the burst lengths of the test signals ts are reduced, a time required to test the device under test DUT may be reduced.

FIGS. 3 and 4 are diagrams for describing a semiconductor device test system 10a according to an embodiment. In detail, FIGS. 3 and 4 are diagrams for describing the test device 100 testing a device under test by using two input and output pads from among data input and output pads included in the device under test. FIGS. 3 and 4 may be described with reference to FIGS. 1 to 2B, and redundant descriptions may be omitted.

Referring to FIG. 3, the semiconductor device test system 10a may correspond to the semiconductor device test system 10 of FIG. 2A. Hereinafter, differences from FIG. 2A will be mainly described while describing FIG. 3. The semiconductor device test system 10a may include the test device 100, the probe card 200, a first device under test 510a, and a second device under test 520a. The test device 100 may include the FAM 110, a comparative circuit 120a, input and output resources 130a, the control circuit 140, and the pattern generator 150.

Referring to FIG. 3, the test device 100 tests two devices, i.e., the first device under test 510a and the second device under test 520a, but this is only an example, and the test device 100 may test more than two devices. When the test device 100 tests the first device under test 510a and the second device under test 520a, the first device under test 510a and the second device under test 520a may operate in a burst mode.

The first device under test 510a may include first pads 511a as external connection pads. The first pads 511a may include a first data input and output pad 511_1a and a second data input and output pad 511_2a. The first device under test 510a may output a first test signal ts1 through the first data input and output pad 511_1a, and output a second test signal ts2 through the second data input and output pad 511_2a. The first test signal ts1 and the second test signal ts2 may be signals obtained by reading values (e.g., test patterns pre-input by the test device 100) stored in a plurality of memory cells included in the first device under test 510a.

The second device under test 520a may include first pads 521a as external connection pads. The first pads 521a may include a first data input and output pad 521_1a and a second data input and output pad 521_2a. The second device under test 520a may output a third test signal ts3 through the first data input and output pad 521_1a, and output a fourth test signal ts4 through the second data input and output pad 521_2a. The third test signal ts3 and the fourth test signal ts4 may be signals obtained by reading values (e.g., test patterns pre-input by the test device 100) stored in a plurality of memory cells included in the second device under test 520a.

According to an embodiment, the first device under test 510a and the second device under test 520a may operate based on a clock signal, a command signal, and an address signal generated by the pattern generator 150. Although not illustrated, the first device under test 510a and the second device under test 520a may receive the clock signal, the command signal, and the address signal through pins other than a data input and output pin, from among a plurality of pins included in the probe card 200.

The input and output resources 130a may include first to fourth input and output terminals 130_1a to 130_4a, and the test device 100 may receive two test signals from each of the first and second devices under test 510a and 520a through the input and output resources 130a. For example, the test device 100 may receive two test signals, i.e., the first test signal ts1 and the second test signal ts2, from the first device under test 510a. Similarly, the test device 100 may receive two test signals, i.e., the third test signal ts3 and the fourth test signal ts4, from the second device under test 520a.

The probe card 200 may receive the first test signal ts1 from the first device under test 510a through a first input and output pin 211_1a. The probe card 200 may provide the first test signal ts1 to the test device 100 through a first input and output terminal 130_1a.

The probe card 200 may receive the second test signal ts2 from the first device under test 510a through a second input and output pin 211_2a. The probe card 200 may provide the second test signal ts2 to the test device 100 through a second input and output terminal 130_2a.

The probe card 200 may receive the third test signal ts3 from the second device under test 520a through a third input and output pin 211_3a. The probe card 200 may provide the third test signal ts3 to the test device 100 through a third input and output terminal 130_3a.

The probe card 200 may receive the fourth test signal ts4 from the second device under test 520a through a fourth input and output pin 211_4a. The probe card 200 may provide the fourth test signal ts4 to the test device 100 through a fourth input and output terminal 130_4a.

The comparative circuit 120a may include first to fourth comparators C1 to C4. The first comparator C1 may receive the first test signal ts1 through the first input and output terminal 130_1a, and compare the first test signal ts1 with a test reference voltage VOH. The first comparator C1 may generate a first test result signal trs1, based on a result of comparing the first test signal ts1 with the test reference voltage VOH.

According to an embodiment, the test reference voltage VOH may be generated by the control circuit 140, but this is only an example, and the test reference voltage VOH may be generated through a separate voltage generation circuit included in the test device 100.

The second comparator C2 may receive the second test signal ts2 through the second input and output terminal 130_2a, and compare the second test signal ts2 with the test reference voltage VOH. The second comparator C2 may generate a second test result signal trs2, based on a result of comparing the second test signal ts2 with the test reference voltage VOH.

The third comparator C3 may receive the third test signal ts3 through the third input and output terminal 130_3a, and compare the third test signal ts3 with the test reference voltage VOH. The third comparator C3 may generate a third test result signal trs3, based on a result of comparing the third test signal ts3 with the test reference voltage VOH.

The fourth comparator C4 may receive the fourth test signal ts4 through the fourth input and output terminal 130_4a, and compare the fourth test signal ts4 with the test reference voltage VOH. The fourth comparator C4 may generate a fourth test result signal trs4, based on a result of comparing the fourth test signal ts4 with the test reference voltage VOH.

Test result signals generated by the comparative circuit 120a may include information related to a memory cell that has not passed a test from among memory cells of a device under test (e.g., addresses of memory cells that have not passed a test). According to an embodiment, when a value indicated by the first test signal ts1 is greater than the test reference voltage VOH, the first comparator C1 may generate the first test result signal trs1 indicating that test results of the memory cells of the first device under test 510a is a pass. When the value indicated by the first test signal ts1 is less than the test reference voltage VOH, the first comparator C1 may generate the first test result signal trs1 including information related to a memory cell in which a test result is a fail, from among the memory cells of the first device under test 510a, corresponding to the first test signal ts1. The second test result signal trs2 to the fourth test result signal trs4 may be generated in a same manner as the first test result signal trs1, and redundant descriptions are omitted.

Referring to FIG. 4, a diagram in which the test device 100 reads the first test signal ts1 and the second test signal ts2 from the first device under test 510a, according to the clock signal CLK generated by the pattern generator 150, is illustrated.

According to an embodiment, a total of 288 burst durations may be required to read data (e.g., input test pattern data) stored in the memory cell of the first device under test 510a of FIG. 3. A burst length of the first test signal ts1 and the second test signal ts2 may be a first burst length RT1, and the first device under test 510a of FIG. 3 outputs a test signal to the test device 100 through two data input and output pads, i.e., the first and second data input and output pads 511_1a and 511_2a. For example, the first burst length RT1 may be 144. Each of the first test signal ts1 and the second test signal ts2 may include a total of 144 burst durations, i.e., first burst duration BL1 to 144th burst duration BL144. Each burst duration may correspond to a data signal for reading a plurality cells from among a plurality of memory cell arrays included in the first device under test 510a. For example, the first burst duration BL1 may correspond to a data signal for reading M adjacent memory cells (M is an integer of 1 or greater) from among the memory cell arrays of the first device under test 510a. Like the first burst duration BL1, the second burst duration BL2 to the 144th burst duration BL144 may each correspond to a data signal for reading M adjacent memory cells from among the memory cell arrays of the first device under test 510a.

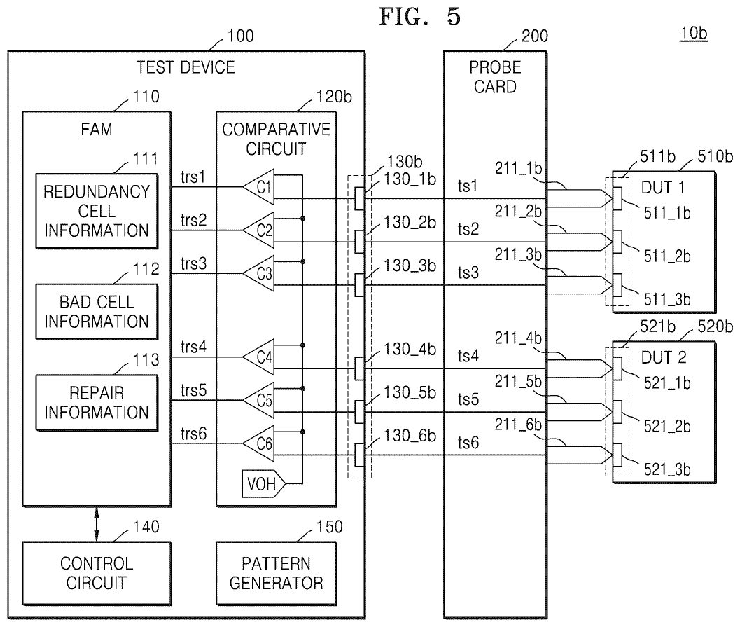

When electrically testing devices under test, the test device 100 may assign, to each device under test, only two input and output terminals among the input and output resources 130a as shown in FIG. 3, but a burst length of test signals may be reduced when the number of terminals assigned to each device under test is increased. In this regard, an example of assigning three input and output terminals to each device under test will be described with reference to FIGS. 5 and 6.

FIGS. 5 and 6 are diagrams for describing a semiconductor device test system 10b according to an embodiment. In detail, FIGS. 5 and 6 are diagrams for describing the test device 100 testing a device under test by using three input and output pads from among data input and output pads included in the device under test. FIGS. 5 and 6 may be described with reference to FIGS. 1 to 4, and redundant descriptions may be omitted.

Referring to FIG. 5, the semiconductor device test system 10b may correspond to the semiconductor device test system 10 of FIG. 2A. Hereinafter, differences from FIG. 2A will be mainly described while describing FIG. 5. The semiconductor device test system 10b may include the test device 100, the probe card 200, a first device under test 510b, and a second device under test 520b. The test device 100 may include the FAM 110, a comparative circuit 120b, input and output resources 130b, the control circuit 140, and the pattern generator 150.

Referring to FIG. 5, the test device 100 tests two devices, i.e., the first device under test 510b and the second device under test 520b, but this is only an example, and the test device 100 may test more than two devices. When the test device 100 tests the first device under test 510b and the second device under test 520b, the first device under test 510b and the second device under test 520b may operate in a burst mode.

The first device under test 510b may include first pads 511b as external connection pads. The first pads 511b may include a first data input and output pad 511_1b, a second data input and output pad 511_2b, and a third data input and output pad 511_3b. The first device under test 510b may output the first test signal ts1 through the first data input and output pad 511_1b, output the second test signal ts2 through the second data input and output pad 511_2b, and output the third test signal ts3 through the third data input and output pad 511_3b. The first test signal ts1, the second test signal ts2, and the third test signal ts3 may be signals obtained by reading values (e.g., test patterns pre-input by the test device 100) stored in memory cells of the first device under test 510b.

The second device under test 520b may include first pads 521b as external connection pads. The first pads 521b may include a first data input and output pad 521_1b, a second data input and output pad 521_2b, and a third data input and output pad 521_3b. The second device under test 520b may output the fourth test signal ts4 through the first data input and output pad 521_1b, a fifth test signal ts5 through the second data input and output pad 521_2b, and a sixth test signal ts6 through the third data input and output pad 521_3b. The fourth test signal ts4, the fifth test signal ts5, and the sixth test signal ts6 may be signals obtained by reading values (e.g., test patterns pre-input by the test device 100) stored in memory cells of the second device under test 520b.

According to an embodiment, the first device under test 510b and the second device under test 520b may operate based on a clock signal, a command signal, and an address signal generated by the pattern generator 150. Although not illustrated, the first device under test 510b and the second device under test 520b may receive the clock signal, the command signal, and the address signal through pins other than a data input and output pin, from among a plurality of pins included in the probe card 200.

Referring to FIG. 5, the input and output resources 130b may include first to sixth input and output terminals 130_1b to 130_6b, and the test device 100 may receive three test signals from each of the first and second devices under test 510b and 520b through the input and output resources 130b. For example, the test device 100 may receive three test signals, i.e., the first test signal ts1, the second test signal ts2, and the third test signal ts3, from the first device under test 510b. Similarly, the test device 100 may receive three test signals, i.e., the fourth test signal ts4, the fifth test signal ts5, and the sixth test signal ts6, from the second device under test 520b.

The probe card 200 may receive the first test signal ts1 from the first device under test 510b through a first input and output pin 211_1b. The probe card 200 may provide the first test signal ts1 to the test device 100 through a first input and output terminal 130_1b.

The probe card 200 may receive the second test signal ts2 from the first device under test 510b through a second input and output pin 211_2b. The probe card 200 may provide the second test signal ts2 to the test device 100 through a second input and output terminal 130_2b.

The probe card 200 may receive the third test signal ts3 from the first device under test 510b through a third input and output pin 211_3b. The probe card 200 may provide the third test signal ts3 to the test device 100 through a third input and output terminal 130_3b.

The probe card 200 may receive the fourth test signal ts4 from the second device under test 520b through a fourth input and output pin 211_4b. The probe card 200 may provide the fourth test signal ts4 to the test device 100 through a fourth input and output terminal 130_4b.

The probe card 200 may receive the fifth test signal ts5 from the second device under test 520b through a fifth input and output pin 211_5b. The probe card 200 may provide the fifth test signal ts5 to the test device 100 through a fifth input and output terminal 130_5b.

The probe card 200 may receive the sixth test signal ts6 from the second device under test 520b through a sixth input and output pin 211_6b. The probe card 200 may provide the sixth test signal ts6 to the test device 100 through a sixth input and output terminal 130_6b.

The comparative circuit 120b may include first to sixth comparators C1 to C6. The first comparator C1 may receive the first test signal ts1 through the first input and output terminal 130_1b, and compare the first test signal ts1 with the test reference voltage VOH. The first comparator C1 may generate the first test result signal trs1, based on the result of comparing the first test signal ts1 with the test reference voltage VOH.

The second comparator C2 may receive the second test signal ts2 through the second input and output terminal 130_2b, and compare the second test signal ts2 with the test reference voltage VOH. The second comparator C2 may generate the second test result signal trs2, based on the result of comparing the second test signal ts2 with the test reference voltage VOH.

The third comparator C3 may receive the third test signal ts3 through the third input and output terminal 130_3b, and compare the third test signal ts3 with the test reference voltage VOH. The third comparator C3 may generate the third test result signal trs3, based on the result of comparing the third test signal ts3 with the test reference voltage VOH.

The fourth comparator C4 may receive the fourth test signal ts4 through the fourth input and output terminal 130_4b, and compare the fourth test signal ts4 with the test reference voltage VOH. The fourth comparator C4 may generate the fourth test result signal trs4, based on the result of comparing the fourth test signal ts4 with the test reference voltage VOH.

The fifth comparator C5 may receive the fifth test signal ts5 through the fifth input and output terminal 130_5b, and compare the fifth test signal ts5 with the test reference voltage VOH. The fifth comparator C5 may generate a fifth test result signal trs5, based on a result of comparing the fifth test signal ts5 with the test reference voltage VOH.

The sixth comparator C6 may receive the sixth test signal ts6 through the sixth input and output terminal 130_6b, and compare the sixth test signal ts6 with the test reference voltage VOH. The sixth comparator C6 may generate a sixth test result signal trs6, based on a result of comparing the sixth test signal ts6 with the test reference voltage VOH.

Referring to FIG. 6, a diagram in which the test device 100 reads the first test signal ts1, the second test signal ts2, and the third test signal ts3 from the first device under test 510b, according to the clock signal CLK generated by the pattern generator 150 of FIG. 5, is illustrated.

According to an embodiment, a total of 288 burst durations may be required to read data (e.g., input test pattern data) stored in a memory cell of the first device under test 510b of FIG. 5, as in the reading of the data stored in the memory cell of the first device under test 510a of FIG. 3.

The first device under test 510b of FIG. 5 may output test signals to the test device 100 by further using one more data input and output pads, compared to the first device under test 510a of FIG. 3. Accordingly, a burst length of the first test signal ts1, the second test signal ts2, and the third test signal ts3 may be a second burst length RT2, and the first device under test 510b of FIG. 5 outputs a test signal to the test device 100 through three data input and output pads, i.e., the first to third data input and output pads 511_1b to 511_3b, and thus, the second burst length RT2 may be 96.

The first test signal ts1, the second test signal ts2, and the third test signal ts3 may include a total of 96 burst durations, i.e., the first burst duration BL1 to 96th burst duration BL96.

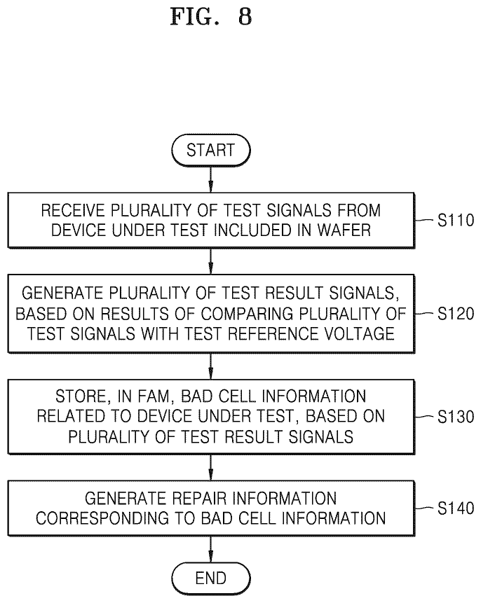

Comparing the graph of FIG. 6 with that of FIG. 4, it is determined that when the number of input and output terminals of the test device 100, assigned to each device under test, is increased, a burst length of a test signal read from the device under test may be reduced, and thus, a test time required to test the device under test may be reduced. However, the number of input and output terminals included in the test device 100 is physically restricted, and thus, the number of input and output terminals of the test device 100, assigned to devices under test, may be adjusted based on the number of semiconductor devices included in the wafer WF of FIG. 2A. In this regard, an example of adjusting the number of input and output terminals will be described below with reference to FIGS. 7A to 8.

FIGS. 7A and 7B are tables for describing a burst length of a test signal when a test is performed on devices under test, according to a semiconductor device test system, according to an embodiment. In detail, FIG. 7A is a table showing a burst length when the input and output terminals of the test device 100 are assigned to each device under test DUT in units of power-of-two, and FIG. 7B is a table showing a burst length when the input and output terminals of the test device 100 are assigned to each device under test DUT in units of integers of non-power-of-two. FIGS. 7A and 7B may be described with reference to FIG. 2A, and redundant descriptions may be omitted.

Hereinafter, for convenience of description, an example embodiment is described in which it is assumed that the number of first to Nth input and output terminals 130_1 to 130_N included in the input and output resources 130 of the semiconductor device test system 10 is 6144. That is, N=6144. However, this is only an example and a value of N may be smaller or greater. Also, it is assumed that a total of 288 burst durations may be required for the test device 100 of FIG. 1 to read data (e.g., input test pattern data) stored in the memory cell of the device under test DUT.

Referring to FIG. 7A, a burst length may be as follows when the number of input and output terminals of the test device 100, assigned to each device under test DUT, is adjusted in units of power-of-two.

According to an embodiment, when the number of devices under test DUT formed on the wafer WF is greater than a first reference value ref1 but smaller than a second reference value ref2, four input and output terminals may be assigned to each device under test DUT, and the assigning of the four input and output terminals to each device under test DUT as such may be referred to as parallel bit text (PBT)×4. Here, a burst length of a text signal may be 72. The first reference value ref1 may be, for example, 768, and the second reference value ref2 may be, for example, 877.

According to an embodiment, when the number of device under test DUT formed on the wafer WF is greater than the second reference value ref2 but smaller than a third reference value ref3, four input and output terminals may still be assigned to each device under test DUT. Here, a burst length of a text signal may be 72. The third reference value ref3 may be, for example, 1013.

According to an embodiment, when the number of device under test DUT formed on the wafer WF is greater than the third reference value ref3 but smaller than a fourth reference value ref4, four input and output terminals may still be assigned to each device under test DUT. Here, a burst length of a text signal may be 72. The fourth reference value ref4 may be, for example, 1228.

According to an embodiment, when the number of device under test DUT formed on the wafer WF is greater than the fourth reference value ref4 but smaller than a fifth reference value ref5, four input and output terminals may still be assigned to each device under test DUT. Here, a burst length of a text signal may be 72. The fifth reference value ref5 may be, for example, 1536.

According to an embodiment, when the number of device under test DUT formed on the wafer WF is greater than the fifth reference value ref5 but smaller than a sixth reference value ref6, two input and output terminals may be assigned to each device under test DUT. Here, a burst length of a test signal may be 144. The sixth reference value ref6 may be, for example, 2048.

Referring to FIG. 7B, a burst length may be as follows when the number of input and output terminals of the test device 100, assigned to each device under test DUT, is adjusted in units of integers of non-power-of-two.

According to an embodiment, when the number of device under test DUT formed on the wafer WF is greater than the first reference value ref1 but smaller than the second reference value ref2, seven input and output terminals may be assigned to (e.g., electrically connected to) each device under test DUT. Here, a burst length of a text signal may be 42.

According to an embodiment, when the number of device under test DUT formed on the wafer WF is greater than the second reference value ref2 but smaller than the third reference value ref3, six input and output terminals may be assigned to each device under test DUT. Here, a burst length of a text signal may be 48.

According to an embodiment, when the number of device under test DUT formed on the wafer WF is greater than the third reference value ref3 but smaller than the fourth reference value ref4, five input and output terminals may be assigned to each device under test DUT. Here, a burst length of a text signal may be 58.

According to an embodiment, when the number of device under test DUT formed on the wafer WF is greater than the fourth reference value ref4 but smaller than the fifth reference value ref5, four input and output terminals may be assigned to each device under test DUT. Here, a burst length of a text signal may be 72.

According to an embodiment, when the number of device under test DUT formed on the wafer WF is greater than the fifth reference value ref5 but smaller than the sixth reference value ref6, three input and output terminals may be assigned to each device under test DUT. Here, a burst length of a text signal may be 96.

As described above, when the number of input and output terminals of the test device 100, assigned to each device under test DUT, is adjusted in units of integers of non-power-of-two, burst lengths of test signals may be reduced compared to when the number of input and output terminals of the test device 100, assigned to each device under test DUT, is adjusted in units of power-of-two.

For example, the number of input and output terminals of the test device 100 that is assigned to each device under test DUT may be determined by dividing the total number of available input and output terminals of the test device 100 by the total number of devices under test DUT and rounding down to the nearest integer. For example, as shown in FIG. 7B, when a total of N=6144 input and output terminals of the test device 100 are available and the number of devices under test DUT is greater than ref1=768 and less than ref2=877 (e.g., 800), then the number of input and output terminals of the test device 100 assigned to each device under test DUT may be

$$⌊ \frac{6144}{800} ⌋ = 7.$$

In one or more embodiments, the assignment of input and output terminals of the test device 100 to each device under test DUT may be carried out by the control circuit 140 of the test device 100. In one or more embodiments, the assignment of input and output terminals of the test device 100 to each device under test DUT may be carried out by changing an attribute of the probe card 200 such as its shape.

FIG. 8 is a flowchart for describing an operation method of a test device, according to an embodiment. FIG. 8 may be described with reference to FIGS. 2A and 5, and when described with reference to FIG. 5, the first device under test 510b is described as an example for convenience of description, but it is obvious that the second device under test 520b may also be described in the same manner as the first device under test 510b. Hereinafter, details that overlap those described above may be omitted.

Referring to FIG. 8, in operation S110, the test device 100 may receive the plurality of test signals ts from the device under test DUT included in the wafer WF of FIG. 2A.

According to an embodiment, the test device 100 may receive, from the first device under test 510b, the first test signal ts1 to the third test signal ts3.

According to an embodiment, the number of the plurality of test signals ts may be an integer, and for example, the number of the plurality of test signals ts may be an integer of non-power-of-two.

In operation S120, the test device 100 may generate the plurality of test result signals trs, based on results of comparing the plurality of test signals ts with the test reference voltage VOH of FIG. 5.

According to an embodiment, the number of the plurality of test result signals trs may be an integer, and for example, the number of the plurality of test result signals trs may be an integer of non-power-of-two.

According to an embodiment, the test device 100 may generate the first test result signal trs1, based on the result of comparing the first test signal ts1 with the test reference voltage VOH, through the first comparator C1 of the comparative circuit 120b. Similarly, the test device 100 may generate the second test result signal trs2, based on the result of comparing the second test signal ts2 with the test reference voltage VOH, through the second comparator C2 of the comparative circuit 120b. Also, the test device 100 may generate the third test result signal trs3, based on the result of comparing the third test signal ts3 with the test reference voltage VOH, through the third comparator C3 of the comparative circuit 120b.

In operation S130, the test device 100 may store, in the FAM 110, the bad cell information 112 related to the device under test DUT, based on the plurality of test result signals trs.

In operation S140, the test device 100 may generate the repair information 113 corresponding to the bad cell information 112.

According to an embodiment, the test device 100 may include the repair information 113 for repairing bad cells of the first device under test 510b, based on the redundancy cell information 111 and the bad cell information 112, through the control circuit 140.

Hereinabove, embodiments have been described in the drawings and specification. In the present specification, although the embodiments have been described by using specific terms, the terms are used only for descriptive purposes and are not intended to limit the meanings or scope of the inventive concept. Therefore, it will be understood by one of ordinary skill in the art that other modifications and equivalents may be made therein.

1. A test device for performing an electrical test on devices formed on a wafer, the test device comprising:
a plurality of input/output terminals configured to be electrically connected to the devices formed on the wafer;
a comparative circuit configured to receive a plurality of test signals from a device under test formed on the wafer, and generate a plurality of test result signals, based on the plurality of test signals; and
a memory configured to receive the plurality of test result signals and store bad cell information and repair information related to the device under test, which are indicated by the plurality of test result signals,
wherein the total number of the plurality of test signals received from the device under test at one time is an integer.

2. The test device of claim 1, wherein the total number of the plurality of test signals corresponds to an integer of non-power-of-two.

3. The test device of claim 1, wherein the total number of the plurality of test result signals generated at one time is an integer other than a power of two.

4. The test device of claim 1, wherein the plurality of test signals are each input through an independent input/output terminal from among the plurality of input/output terminals.

5. The test device of claim 1, wherein, among the plurality of input/output terminals, the total number of input/output terminals electrically connected to the device under test is an integer other than a power of two.

6. The test device of claim 1, wherein the plurality of input/output terminals are electrically connected to a plurality of data input/output pads of the devices formed on the wafer.

7. The test device of claim 1, wherein, when a number of devices formed on the wafer is more than a first reference value but less than a second reference value, the total number of input/output terminals electrically connected to the device under test is N, wherein N is an integer of 2 or greater, and
when the number of devices formed on the wafer is more than the second reference value but less than a third reference value, the total number of input/output terminals electrically connected to the device under test is N−1.

8. The test device of claim 1, wherein the test device is configured to perform the electrical test on the devices formed on the wafer, in parallel.

9. The test device of claim 1, wherein the comparative circuit comprises a plurality of comparators configured to generate the plurality of test result signals, based on results of comparing the plurality of test signals with a test reference voltage, and
the total number of the plurality of comparators is an integer other than a power of two.

10. The test device of claim 1, wherein the test device is configured to generate the bad cell information related to the device under test, based on the plurality of test result signals received by the memory, and
the test device further comprises a control circuit configured to generate the repair information corresponding to the bad cell information.

11. The test device of claim 10, wherein the bad cell information related to the device under test comprises bad cell addresses of the device under test, included in the plurality of test result signals, and
the repair information comprises repair cell addresses respectively corresponding to the bad cell addresses.

12. An operating method of a test device for performing an electrical test on devices formed on a wafer, the operating method comprising:
receiving a plurality of test signals from a device under test formed on the wafer;
generating a plurality of test result signals, based on results of comparing the received plurality of test signals with a test reference voltage;
storing bad cell information related to the device under test in a memory of the test device, based on the plurality of test result signals; and
generating repair information corresponding to the bad cell information,
wherein the total number of the plurality of test signals received from the device under test at one time is an integer.

13. The operating method of claim 12, wherein the total number of the plurality of test signals corresponds to an integer of non-power-of-two.

14. The operating method of claim 12, wherein the total number of the plurality of test result signals generated at one time is an integer other than a power of two.

15. A test system for performing an electrical test on devices formed on a wafer, the test system comprising:
a probe card including a plurality of input/output pins configured to be electrically connected to the devices formed on the wafer; and
a test device configured to test a device under test formed on the wafer,
wherein the probe card is configured to receive a plurality of test signals through the plurality of input/output pins from the device under test, and provide the received plurality of test signals to the test device,
wherein the test device comprises:
a plurality of input/output terminals configured to receive the plurality of test signals from the probe card;
a comparative circuit configured to generate a plurality of test result signals, based on the plurality of test signals; and
a memory configured to receive the plurality of test result signals and store bad cell information and repair information related to the device under test, which are indicated by the plurality of test result signals,
wherein the total number of input and output pins from among the plurality of input/output pins electrically connected to the device under test is an integer.

16. The test system of claim 15, wherein the total number of the plurality of test signals received from the device under test at one time is an integer other than a power of two.

17. The test system of claim 15, wherein the total number of the plurality of test result signals generated at one time is an integer other than a power of two.

18. The test system of claim 15, wherein the plurality of test signals are each input through an independent input/output pin, and
among the plurality of input/output pins, the number of input/output pins electrically connected to the device under test is an integer other than a power of two.

19. The test system of claim 15, wherein the plurality of input/output pins are electrically connected to a plurality of data input/output pads of the devices formed on the wafer.

20. The test system of claim 15, wherein the test system is configured to perform the electrical test on the devices formed on the wafer, in parallel.

21-23. (canceled)
